(19) United States
(12) Patent Application Publication
(10) Pub. No.: US 2022/0302023 A1
(43) Pub. Date: Sep. 22, 2022

(54) SEMICONDUCTOR DEVICE AND MANUFACTURING METHOD THEREOF

(71) Applicant: Kioxia Corporation, Tokyo (JP)

(72) Inventor: Akitsugu HATAZAKI, Yokkaichi Mie (JP)

(73) Assignee: Kioxia Corporation, Tokyo (JP)

(21) Appl. No.: 17/462,643

(22) Filed: Aug. 31, 2021

(30) Foreign Application Priority Data
Mar. 17, 2021 (JP) 2021-043775

(51) Int. Cl. H01L 23/522; H01L 21/768

(52) U.S. Cl. CPC H01L 23/5226; H01L 21/76844; H01L 21/76802; H01L 21/76846; H01L 27/11582

(57) ABSTRACT

A semiconductor device according to the present embodiment comprises a first electrode film. An interlayer dielectric film is provided on the first electrode film. A contact plug is provided in a contact hole that penetrates through the interlayer dielectric film and reaches the first electrode film. The contact plug includes a first metal film and a first conductive film configured to cover an inner wall of an upper portion of the contact hole. The contact plug includes a second metal film configured to cover the first conductive film on the inner wall of the upper portion of the contact hole and cover an inner wall of a lower portion of the contact hole. The contact plug includes a second conductive film configured to be filled inside the second metal film in the contact hole.

### CROSS REFERENCE TO RELATED APPLICATIONS

This application is based upon and claims the benefit of priority from the prior Japanese Patent Application No. 2021-043775, filed on Mar. 17, 2021, the entire contents of which are incorporated herein by reference.

### FIELD

The embodiments of the present invention relate to a semiconductor device and manufacturing method thereof.

### BACKGROUND

Some of semiconductor storage devices such as a NAND flash memory include a three-dimensional memory cell array in which a plurality of memory cells are arranged three-dimensionally. The number of stacked word lines in such a three-dimensional memory cell array has increased in recent years. Therefore, formation of a contact plug connected to each word line requires a contact hole with a high aspect ratio.

Such a contact hole with a high aspect ratio is formed in a tapered shape in which its upper portion is wider because an inner wall of the upper portion is etched to some extent, and the diameter is reduced toward the bottom portion. Therefore, the upper portion of the contact hole may come into contact with another structure unintentionally. This contact causes a failure such as short circuit between wires.

### BRIEF DESCRIPTION OF THE DRAWINGS

FIG. 1 is a schematic perspective view of an example of a semiconductor device according to the present embodiment;

FIG. 2 is a schematic plan view of a stack in FIG. 1;

FIGS. 3 and 4 are schematic cross-sectional views of an example of a memory cell having a three-dimensional configuration;

FIG. 5 is a plan view illustrating a configuration example of a border between the memory cell array and the step portion;

FIG. 6 is a schematic plan view illustrating an arrangement example of the contact plug and the insulator columns therearound;

FIG. 7 is a schematic cross-sectional view illustrating a configuration example of the contact plug;

FIG. 8 is a schematic plan view illustrating a configuration example of the contact plug;

FIGS. 9 to 14 are schematic plan views illustrating an example of a manufacturing method of a semiconductor device according to the present embodiment;

FIG. 15 is a schematic cross-sectional view illustrating a configuration example of a contact hole according to a comparative example;

FIG. 16 is a schematic cross-sectional view illustrating a configuration example of a contact plug according to the comparative example;

FIG. 17 is a schematic cross-sectional view illustrating a configuration example of the contact plug and its adjacent one of the insulator columns according to the comparative example; and

FIG. 18 is a schematic cross-sectional view illustrating an example in which a contact plug according to the present embodiment is applied to the contact plugs in the step portion.

### DETAILED DESCRIPTION

Embodiments will now be explained with reference to the accompanying drawings. The present invention is not limited to the embodiments. In the embodiments, “an upper direction” or “a lower direction” refers to a relative direction when a direction perpendicular to a surface of a semiconductor substrate on which semiconductor elements are provided is assumed as “an upper direction”. Therefore, the term “upper direction” or “lower direction” occasionally differs from an upper direction or a lower direction based on a gravitational acceleration direction. In the present specification and the drawings, elements identical to those described in the foregoing drawings are denoted by like reference characters and detailed explanations thereof are omitted as appropriate.

A semiconductor device according to the present embodiment comprises a first electrode film. An interlayer dielectric film is provided on the first electrode film. A contact plug is provided in a contact hole that penetrates through the interlayer dielectric film and reaches the first electrode film. The contact plug includes a first metal film and a first conductive film configured to cover an inner wall of an upper portion of the contact hole. The contact plug includes a second metal film configured to cover the first conductive film on the inner wall of the upper portion of the contact hole and cover an inner wall of a lower portion of the contact hole. The contact plug includes a second conductive film configured to be filled inside the second metal film in the contact hole.

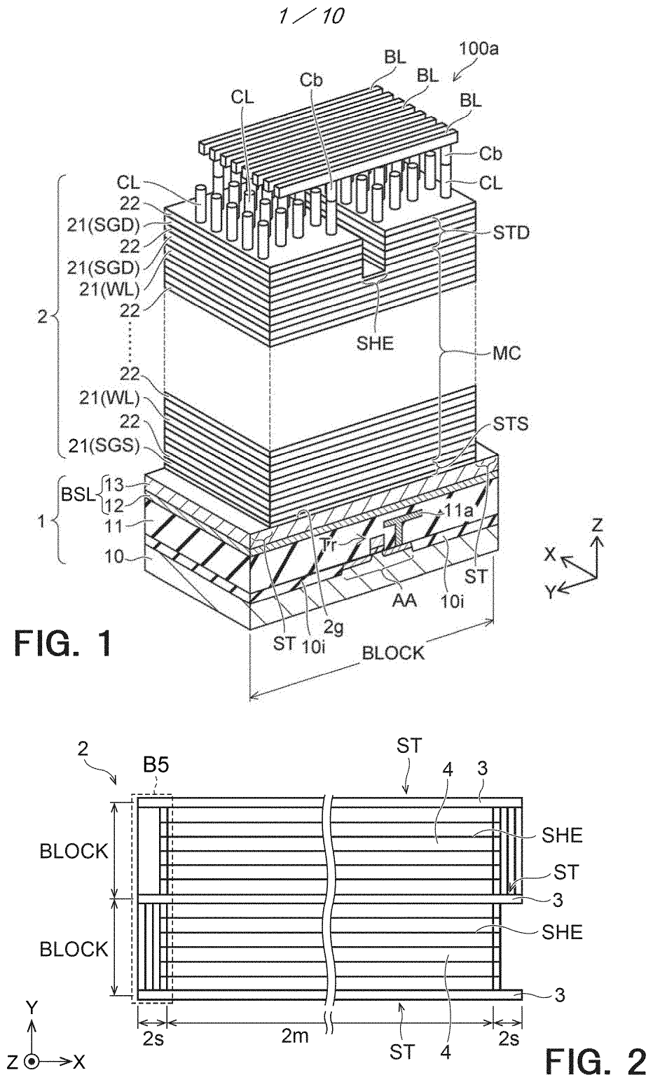

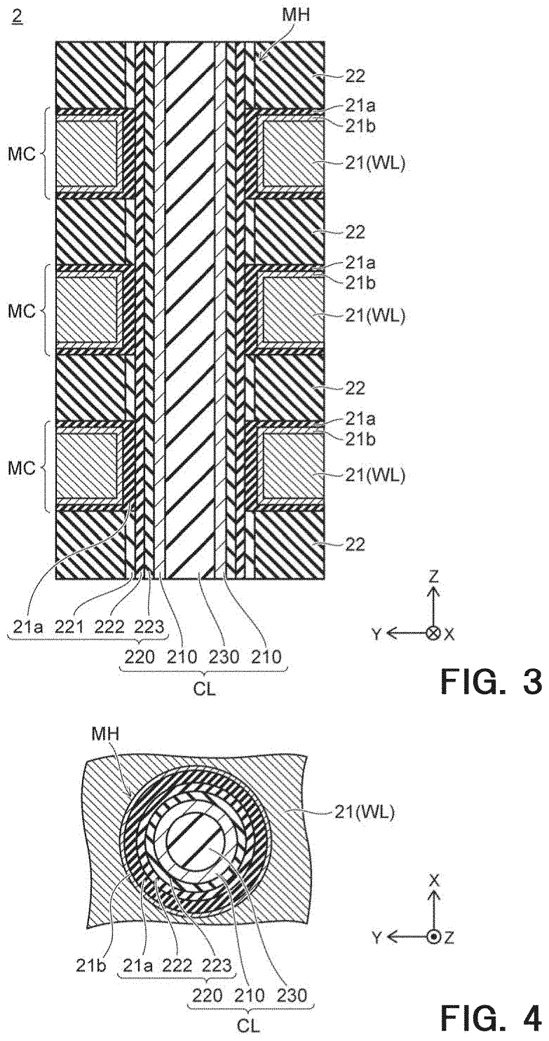

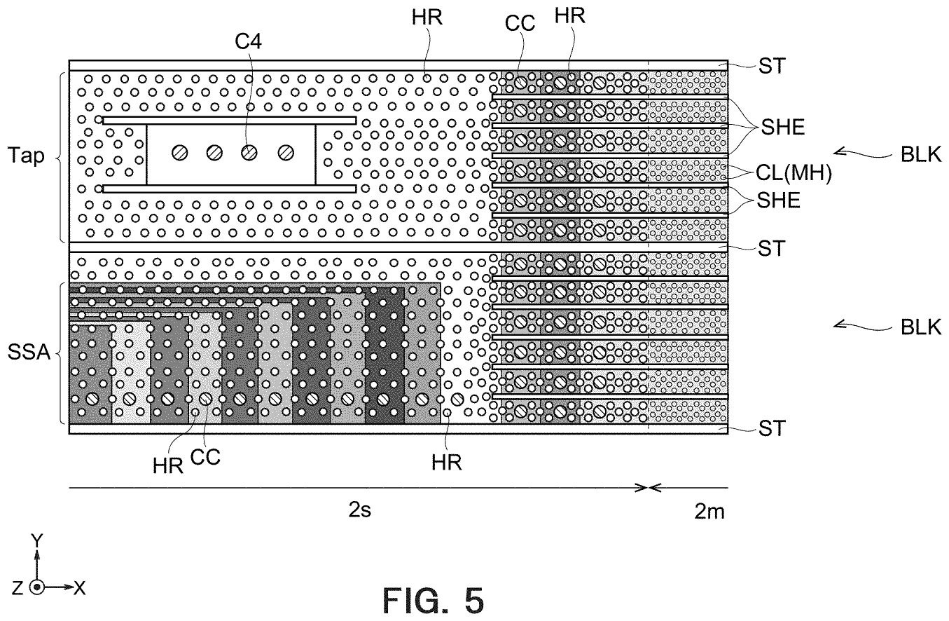

FIG. 1 is a schematic perspective view of an example of a semiconductor device (for example, a semiconductor storage device 100a) according to the present embodiment. FIG. 2 is a schematic plan view of a stack 2 in FIG. 1. In the present specification, a stacking direction of the stack 2 is assumed as a Z-direction. One direction that crosses the Z-direction, for example, at right angles is assumed as a Y-direction. One direction that crosses the Z-direction and the Y-direction, for example, at right angles is assumed as an X-direction. FIGS. 3 and 4 are schematic cross-sectional views of an example of a memory cell having a three-dimensional configuration.

As illustrated in FIGS. 1 to 4, the semiconductor storage device 100a according to a first embodiment is a non-volatile memory including memory cells having a three-dimensional configuration.

The semiconductor storage device 100a includes a base portion 1, the stack 2, a deep slit ST (a plate-shaped portion 3), a shallow slit SHE (a plate-shaped portion 4), and a plurality of column portions CL.

The base portion 1 includes a substrate 10, an interlayer dielectric film 11, a conductive layer 12, and a semiconductor portion 13. The interlayer dielectric film 11 is provided on the substrate 10. The conductive layer 12 is provided on the interlayer dielectric film 11. The semiconductor portion 13 is provided on the conductive layer 12.

The substrate 10 is a semiconductor substrate, for example, a silicon substrate. The conductivity type of silicon (Si) is, for example, a p-type. An element isolation region 10i, for example, is provided in a surface region of the substrate 10. The element isolation region 10i is an insulating region that contains silicon oxide (SiO₂), for example, and defines an active area AA in the surface region of the substrate 10. A source region and a drain region of a transistor Tr are provided in the active area AA. The transistor Tr forms a peripheral circuit (a CMOS (Complementary Metal Oxide Semiconductor) circuit) of the non-volatile memory. The CMOS circuit is provided below a built-in source layer BSL and on the substrate 10. The interlayer dielectric film 11 contains, for example, silicon oxide and insulates the transistor Tr. A wire 11a is provided in the interlayer dielectric film 11. A portion of the wire 11a is electrically connected to the transistor Tr. The conductive layer 12 contains conductive metal, for example, tungsten (W). The semiconductor portion 13 contains, for example, silicon. The conductivity type of silicon is, for example, an n-type. The semiconductor portion 13 may be formed by a plurality of layers, and a portion thereof may contain undoped silicon. Further, either the conductive layer 12 or the semiconductor portion 13 may be omitted.

The conductive layer 12 and the semiconductor portion 13 serve as a common source line of a memory cell array (2m in FIG. 2). The conductive layer 12 and the semiconductor portion 13 are electrically connected to each other as an integrated conductive film and are also referred to as the built-in source layer BSL collectively.

The stack 2 is provided above the substrate 10 and is located in the Z-direction with respect to the conductive layer 12 and the semiconductor portion 13 (the built-in source layer BSL). The stack 2 is configured by a plurality of electrode films 21 and a plurality of insulation layers 22 alternately stacked along the Z-direction. The electrode films 21 contain conductive metal, for example, tungsten. The insulation layers 22 contain silicon oxide, for example. The insulation layers 22 insulate the electrode films 21 from each other. The number of each of the stacked electrode films 21 and the stacked insulation layers 22 may be any number. The insulation layer 22 may be an air gap, for example. An insulation film 2g, for example, is provided between the stack 2 and the semiconductor portion 13. The insulation film 2g contains silicon oxide, for example. The insulation film 2g may contain a high dielectric material having a higher relative permittivity than silicon oxide. The high dielectric material may be metal oxide, for example.

The electrode films 21 include at least one source-side selection gate SGS, a plurality of word lines WL, and at least one drain-side selection gate SGD. The source-side selection gate SGS is a gate electrode of a source-side selection transistor STS. The word lines WL serve as gate electrodes of memory cells MC. The drain-side selection gate SGD is a gate electrode of a drain-side selection transistor STD. The source-side selection gate SGS is provided in a lower region of the stack 2. The drain-side selection gate SGD is provided in an upper region of the stack 2. The lower region is a region of the stack 2 closer to the base portion 1, and the upper region is a region of the stack 2 farther from the base portion 1. The word lines WL are provided between the source-side selection gate SGS and the drain-side selection gate SGD.

The thickness in the Z-direction of one of the insulation layers 22 which insulates the source-side selection gate SGS and the word line WL from each other may be larger than the thickness in the Z-direction of the insulation layer 22 that insulates the word lines WL from each other, for example. Further, a cover insulation film (not illustrated) may be provided on the uppermost insulation layer 22 that is the farthest from the base portion 1. The cover insulation film contains silicon oxide, for example.

The semiconductor storage device 100a includes the memory cells MC connected in series between the source-side selection transistor STS and the drain-side selection transistor STD. The configuration in which the source-side selection transistor STS, the memory cells MC, and the drain-side selection transistor STD are connected in series is called “memory string” or “NAND string”. The memory string is connected to bit lines BL, for example, via contacts Cb. The bit lines BL are provided above the stack 2 and extend in the Y-direction.

The deep slits ST and the shallow slits SHE are provided in the stack 2. The deep slits ST extend in the X-direction, and are provided in the stack 2 while penetrating through the stack 2 from an upper end of the stack 2 to the base portion 1. The plate-shaped portion 3 is a wire provided in the deep slit ST (FIG. 2). The plate-shaped portion 3 is formed by a conductive film that is electrically insulated from the stack 2 by an insulation film (not illustrated) provided on an inner wall of the deep slit ST and that is electrically connected to the built-in source layer BSL embedded in the deep slit ST. The plate-shaped portion 3 is filled with an insulation material such as a silicon oxide film in some cases. Meanwhile, the shallow slits SHE extend in the X-direction and are provided from the upper end of the stack 2 to the middle in the stack 2. The shallow slits SHE penetrate through the upper region of the stack 2 in which the drain-side selection gate SGD is provided. The plate-shaped portion 4, for example, is provided in the shallow slit SHE (FIG. 2). The plate-shaped portion 4 is made of silicon oxide, for example.

As illustrated in FIG. 2, the stack 2 includes a step portion 2s and the memory cell array 2m. The step portion 2s is provided at an edge of the stack 2. The memory cell array 2m is sandwiched between the step portions 2s or is surrounded by the step portions 2s. The deep slit ST is provided from the step portion 2s at one end of the stack 2 to the step portion 2s at the other end of the stack 2 through the memory cell array 2m. The shallow slit SHE is provided at least in the memory cell array 2m.

A portion of the stack 2 sandwiched between the two plate-shaped portions 3 illustrated in FIG. 2 is called a block (BLOCK). The block is the minimum unit for erasing data, for example. The plate-shaped portion 4 is provided in the block. The stack 2 between the plate-shaped portion 3 and the plate-shaped portion 4 is called a finger. The drain-side selection gate SGD is divided for each finger. Therefore, in data writing and data reading, it is possible to place one finger in a block in a selected state by the drain-side selection gate SDG.

As illustrated in FIG. 3, each of the column portions CL is provided in a memory hole MH formed in the stack 2. Each column portion CL penetrates through the stack 2 from the upper end of the stack 2 along the Z-direction and is provided in the stack 2 and in the built-in source layer BSL. Each of the column portions CL includes a semiconductor body 210, a memory film 220, and a core layer 230. The column portion CL includes the core layer 230 provided at its center, the semiconductor body 210 provided around the core layer 230, and the memory film 220 provided around the semiconductor body 210. The semiconductor body 210 is electrically connected to the built-in source layer BSL. The memory film 220 as a charge storage member has a charge trapping portion between the semiconductor body 210 and the electrode film 21. The column portions CL selected one by one from the respective fingers are connected to one bit line BL in common via the contacts Cb. Each column portion CL is provided in a cell region (2m), for example.

As illustrated in FIG. 4, the shape of the memory hole MH in an X-Y plane is, for example, circular or elliptical. A block insulation film 21a that forms a portion of the memory film 220 may be provided between the electrode film 21 and the insulation layer 22. The block insulation film 21a is, for example, a silicon oxide film or a metal oxide film. One example of the metal oxide is aluminum oxide. A barrier film 21b may be provided between the electrode film 21 and the insulation layer 22 and between the electrode film 21 and the memory film 220. In a case where the electrode film 21 is made of tungsten, for example, titanium nitride, for example, is selected as the barrier film 21b. The block insulation film 21a prevents back tunneling of electric charges from the electrode film 21 toward the memory film 220. The barrier film 21b improves adhesion between the electrode film 21 and the block insulation film 21a.

The shape of the semiconductor body 210 is tubular with a bottom, for example. The semiconductor body 210 contains silicon, for example. This silicon is polysilicon obtained by crystallizing amorphous silicon, for example. The semiconductor body 210 is made of, for example, undoped silicon. Also, the semiconductor body 210 may be made of, for example, p-type silicon. The semiconductor body 210 serves as a channel of each of the drain-side selection transistor STD, the memory cell MC, and the source-side selection transistor STS.

A portion of the memory film 220, other than the block insulation film 21a, is provided between an inner wall of the memory hole MH and the semiconductor body 210. The shape of the memory film 220 is tubular, for example. The memory cells MC each include a storage region between the semiconductor body 210 and the electrode film 21 that serves as the word line WL, and are stacked in the Z-direction. The memory film 220 includes a cover insulation film 221, a charge trapping film 222, and a tunnel insulation film 223, for example. The semiconductor body 210, the charge trapping film 222, and the tunnel insulation film 223 extend in the Z-direction.

The cover insulation film 221 is provided between the insulation layer 22 and the charge trapping film 222. The cover insulation film 221 contains silicon oxide, for example. The cover insulation film 221 protects the charge trapping film 222 from being etched when a sacrifice film (not illustrated) is replaced with the electrode film 21 (in a replacement process). The cover insulation film 221 may be removed from between the electrode film 21 and the memory film 220 in the replacement process. In this case, the block insulation film 21a, for example, is provided between the electrode film 21 and the charge trapping film 222, as illustrated in FIGS. 3 and 4. The cover insulation film 221 may not be included in a case where the replacement process is not performed for forming the electrode film 21.

The charge trapping film 222 is provided between the block insulation film 21a and the cover insulation film 221, and the tunnel insulation film 223. The charge trapping film 222 contains silicon nitride, for example, and includes trap sites therein which trap electric charges. A portion of the charge trapping film 222, sandwiched between the electrode film 21 that serves as the word line WL and the semiconductor body 210, configures a storage region of the memory cell MC as a charge trapping portion. A threshold voltage of the memory cell MC is changed depending on whether any electric charge is present in the charge trapping portion or in accordance with the amount of electric charges trapped in the charge trapping portion. Accordingly, the memory cell MC retains information.

The tunnel insulation film 223 is provided between the semiconductor body 210 and the charge trapping film 222. The tunnel insulation film 223 contains silicon oxide, or contains silicon oxide and silicon nitride, for example. The tunnel insulation film 223 is a potential barrier between the semiconductor body 210 and the charge trapping film 222. For example, electrons and holes each pass (tunnel) through the potential barrier formed by the tunnel insulation film 223, when electrons are injected from the semiconductor body 210 to the charge trapping portion (in a write operation) and when holes are injected from the semiconductor body 210 to the charge trapping portion (in an erase operation).

The core layer 230 is embedded in the space within the tubular semiconductor body 210. The shape of the core layer 230 is columnar, for example. The core layer 230 contains silicon oxide, for example, and is insulative.

FIG. 5 is a plan view illustrating a configuration example of a border between the memory cell array 2m and the step portion 2s. A plurality of the column portions CL are provided in the memory holes MH in the memory cell array 2m. FIG. 5 illustrates a planar layout in a broken-line frame B5 in FIG. 2, although the scale is different.

Each of the column portions CL is provided in the memory hole MH provided in the stack 2. The memory hole MH penetrates through the stack 2 from the upper end of the stack 2 along a stacking direction of the stack 2 (the Z-direction) and extends in the stack 2 and in the semiconductor portion 13. Each of the column portion portions CL includes the semiconductor body 210 as a semiconductor column, the memory film 220, and the core layer 230 as illustrated in FIGS. 3 and 4. The semiconductor body 210 extends in the stacking direction (the Z direction) of the stack 2 and is electrically connected to the semiconductor portion 13. The memory film 220 has a charge trapping portion between the semiconductor body 210 and the electrode film 21. The column portions CL selected one by one from the respective fingers are connected to one bit line BL in common via the contacts Cb in FIG. 1. The column portions CL are provided in the memory cell array 2m.

A tap region Tap and a step region SSA are provided in the step portion 2s other than the memory cell array 2m. The tap region Tap is provided in the block BLK that is adjacent to the step region SSA in the Y-direction with the deep slit ST arranged therebetween. The tap region Tap may be provided between cell regions in the X-direction. The step region SSA may be also provided between the cell regions in the X-direction. The step region SSA is a region where a plurality of contact plugs CC are provided. The step region SSA may include a bridge region electrically connecting the word lines WL in the blocks BLK that are adjacent to each other in the X-direction with the step region SSA arranged therebetween. The tap region Tap is a region where contact plugs C4 are provided. The contact plugs CC and C4 extend in the Z-direction, for example. Each contact plug CC is electrically connected to, for example, the electrode film 21 (that is, the word line WL). The contact plug C4 is electrically connected to, for example, the wire 11a for power supply to the transistor Tr or the like. Low-resistance metal such as copper or tungsten is used for the contact plugs CC and C4. The shallow slits SHE extend in the memory cell array 2m in the X-direction and electrically isolate the drain-side selection gate SGD in every finger.

A plurality of insulator columns HR are provided around the contact plug CC. Each insulator column HR is provided in a hole provided in the stack 2. The insulator column HR penetrates through the stack 2 from the upper end of the stack 2 along the Z-direction and is provided in the stack 2 and in the semiconductor portion 13. An insulator such as a silicon oxide film is used for the insulator column HR. Each insulator column HR may have the same configuration as the column portion CL. The insulator columns HR are provided in the tap region Tap and the step region SSA, for example. The insulator columns HR serve as support members for keeping gaps formed in the step region and the tap region when a sacrifice film (not illustrated) is replaced with the electrode film 21 (in a replacement process). The insulator column HR has a larger diameter (the width in the X-direction or the Y-direction) than the column portion CL.

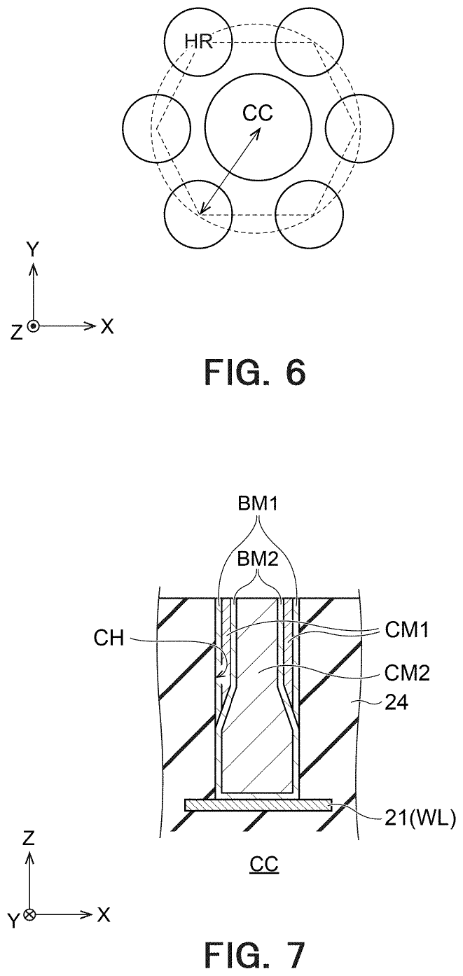

FIG. 6 is a schematic plan view illustrating an arrangement example of the contact plug CC and the insulator columns HR therearound. In the present embodiment, six of the insulator columns HR are arranged around the contact plug CC substantially evenly in plan view a viewed from the Z-direction. The distances from the center of the contact plug CC to the centers of the six insulator columns HR around the contact plug CC are substantially equal to one another. As viewed from the Z-direction, the shape obtained by connecting the centers of the six insulator columns HR is a substantially regular hexagon.

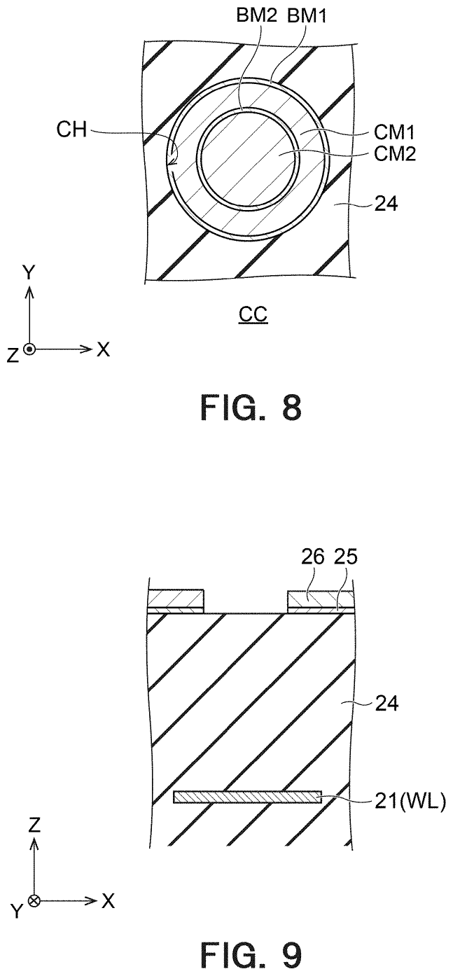

FIG. 7 is a schematic cross-sectional view illustrating a configuration example of the contact plug CC. FIG. 8 is a schematic plan view illustrating a configuration example of the contact plug CC.

The contact plug CC penetrates through the interlayer dielectric film 24 from its top surface to its bottom surface and is electrically connected to a first electrode film 21 (the word line WL). The interlayer dielectric film 24 is provided on the electrode film 21 (the word line WL) in the step portion 2s and electrically insulates the electrode film 21 and a wiring layer (for example, the bit line BL) on the interlayer dielectric film 24 from each other.

The contact plug CC is provided in the contact hole CH that penetrates through the interlayer dielectric film 24 and reaches the electrode film 21. The contact plug CC includes a barrier metal BM1 as a first metal film, a contact material CM1 as a first conductive film, a barrier metal BM2 as a second metal film, and a contact material CM2 as a second conductive film.

The barrier metal BM1 covers the inner wall of the upper portion of the contact hole CH, but does not cover the inner wall of the lower portion of the contact hole CH. That is, the barrier metal BM1 ends between the inner wall of the upper portion and the inner wall of the lower portion of the contact hole CH, and does not continue to the lower portion of the contact hole CH. A metal material containing at least one of titanium nitride (TiN), tungsten nitride (WN), tantalum (Ta), tantalum nitride (TaN), and tungsten (W), for example, is used for the barrier metal BM1. The barrier metal BM1 is deposited under a poor-coverage condition by plasma CVD (Chemical Vapor Deposition), PVD (Physical Vapor Deposition), or the like, in which a process gas is reduced. By this deposition, the barrier metal BM1 is formed only on the inner wall of the upper portion of the contact hole CH which is close to an opening end (an upper end), and is hardly formed below that portion. The barrier metal BM1 covers the inner wall of the upper portion of the contact hole CH over the entire inner circumference.

The contact material CM1 covers the barrier metal BM1 on the inner wall of the upper portion of the contact hole CH, but does not cover the inner wall of the lower portion of the contact hole CH. That is, the contact material CM1 also ends between the inner wall of the upper portion and the inner wall of the lower portion of the contact hole CH, and does not continue to the lower portion of the contact hole CH. A metal material containing at least one of tungsten (W), cobalt (Co), nickel (Ni), molybdenum (Mo), and titanium (Ti), for example, is used for the contact material CM1. The contact material CM1 is a film formed by selective growth on the barrier metal BM1. Accordingly, the contact material CM1 is selectively formed on the barrier metal BM1. The contact material CM1 is formed on the inner wall of the upper portion of the contact hole CH close to the opening end (the upper end), and is hardly formed below that portion, that is, on the inner wall of the lower portion of the contact hole CH close to a lower end, as with the barrier metal BM1. The contact material CM1 covers the inner wall of the upper portion of the contact hole CH over the entire inner circumference.

The barrier metal BM2 covers the contact material CM1 on the inner wall of the upper portion of the contact hole CH, and also covers the inner wall of the lower portion of the contact hole CH. That is, the barrier metal BM2 continues from the inner wall of the upper portion to the inner wall of the lower portion of the contact hole CH, and covers the entire inner wall of the contact hole CH. A metal material containing at least one of titanium nitride (TiN), tungsten nitride (WN), tantalum (Ta), tantalum nitride (TaN), and tungsten (W), for example, is used for the barrier metal BM2, as with the barrier metal BM1. The barrier metals BM1 and BM2 may be made of the same material as each other or different materials from each other. The barrier metal BM2 is deposited under a superior-coverage condition by CVD or the like in which the flow rate of a process gas is sufficient. By this deposition, the barrier metal BM2 is formed from the opening end (the upper end) of the contact hole CH to the lower end. The barrier metal BM2 covers the entire inner wall of the contact hole CH over the entire inner circumference.

The contact material CM2 is filled inside the barrier metal BM2 in the contact hole CH. The contact material CM2 continues from the inner wall of the upper portion to the inner wall of the lower portion of the contact hole CH. A metal material containing at least one of tungsten (W), cobalt (Co), nickel (Ni), molybdenum (Mo), and titanium (Ti), for example, is used for the contact material CM2, as with the contact material CM1. The contact materials CM1 and CM2 may be made of the same material as each other or different materials from each other. The contact material CM2 is formed by selective growth on the barrier metal BM2. Since the barrier metal BM2 is formed on the entire inner wall from the opening end (the upper end) to the lower end of the contact hole CH, the contact material CM2 is embedded in the entire inner wall of the contact hole CH from the opening end (the upper end) to the lower end, as with the barrier metal BM2.

As illustrated in FIG. 8, the contact hole CH has a substantially circular shape in the interlayer dielectric film 24, and the barrier metal BM1, the contact material CM1, the barrier metal BM2, and the contact material CM2 are stacked in that order from outside toward the center in plan view as viewed from the Z-direction. The planar shape of the contact hole CH is not limited to the substantially circular shape, and may be substantially elliptical or substantially rectangular. The barrier metals BM1 and BM2 are films provided for causing the contact materials CM1 and CM2 to grow and may be thinner than the contact materials CM1 and CM2, respectively.

According to the present embodiment, the upper portion of the contact hole CH is formed, and thereafter the inner wall of the upper portion of the contact hole CH is protected by the barrier metal BM1 and the contact material CM1. Accordingly, it is possible to deepen the lower portion of the contact hole CH thereafter, without increasing the width of the upper portion of the contact hole CH. That is, the barrier metal BM1 and the contact material CM1 serve as mask for the inner wall of the upper portion of the contact hole CH, thereby preventing the upper portion of the contact hole CH from being widened more than necessary. Accordingly, the contact hole CH can penetrate through the interlayer dielectric film 24 without coming into contact with the insulator column HR illustrated in FIG. 6.

The insulator column HR is filled with insulator as illustrated in FIG. 17, but may contain voids in some cases. In a case where the contact hole CH comes into contact with the insulator column HR to communicate with the voids, it is likely that a contact material embedded in the contact hole CH enters into the voids in the insulator column HR through the contact hole CH. In this case, the contact material electrically short-circuits the electrode films 21 (that is, the word lines WL) that are adjacent to each other in the Z-direction.

Meanwhile, according to the present embodiment, due to the barrier metal BM1 and the contact material CM1, it is possible to prevent excessive widening of the upper portion of the contact hole CH and to prevent contact of the contact hole CH with the insulator column HR. Accordingly, it is possible to prevent electrical short circuit between the electrode films 21 (that is, the word lines WL) adjacent to each other in the Z-direction.

Next, a manufacturing method of a semiconductor device according to the present embodiment is described.

FIGS. 9 to 14 are schematic plan views illustrating an example of a manufacturing method of a semiconductor device according to the present embodiment. First, a barrier metal 25 and a mask member 26 are formed on the interlayer dielectric film 24 provided on the electrode film 21 in the step portion 2s. The barrier metal 25 is a barrier metal provided for causing the mask member 26 to grow, and is a thin film of, for example, titanium nitride. A metal material such as tungsten is used for the mask member 26. The mask member 26 and the barrier metal 25 are processed to open in a region where the contact hole CH is to be formed. Accordingly, the structure illustrated in FIG. 9 is obtained.

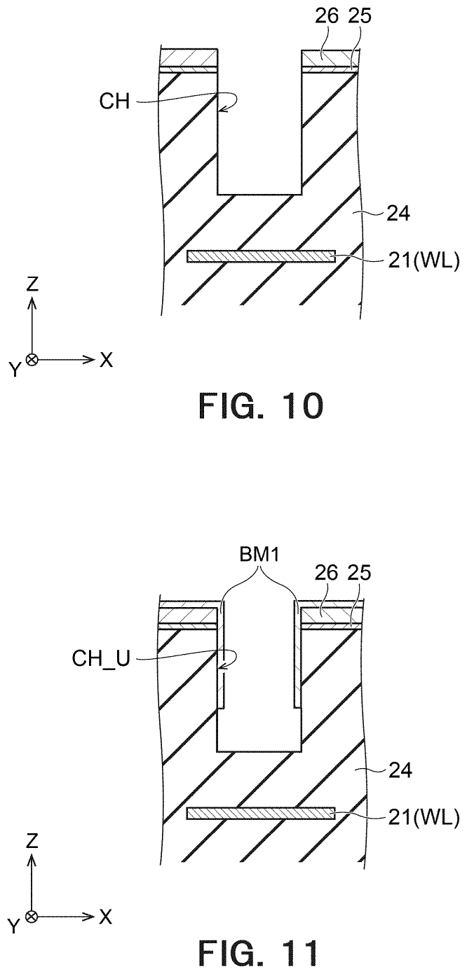

Next, as illustrated in FIG. 10, an upper portion of the interlayer dielectric film 24 is etched by RIE (Reactive Ion Etching) or the like using the mask member 26 as mask. Accordingly, an upper portion CH_U of the contact hole CH is formed in the interlayer dielectric film 24. At this stage, the contact hole CH does not penetrate through the interlayer dielectric film 24 and does not reach the electrode film 21.

Next, the barrier metal BM1 (for example, TiN) is deposited on an inner wall of the upper portion CH_U of the contact hole CH by CVD or the like, as illustrated in FIG. 11. At this time, the barrier metal BM1 is deposited under a poor-coverage condition by plasma CVD (Chemical Vapor Deposition), PVD (Physical Vapor Deposition), or the like, in which a process gas is reduced. By this deposition, the barrier metal BM1 is formed on the inner wall of the upper portion CH_U, which is close to the opening end (the upper end) of the contact hole CH, and is hardly formed below that portion. The barrier metal BM1 covers the inner wall of the upper portion CH_U of the contact hole CH over the entire length in the circumferential direction.

The length in the Z-direction of the barrier metal BM1 in the contact hole CH can be controlled by the deposition condition of the barrier metal BM1. It is preferable that the barrier metal BM1 is provided to such a depth that the inner diameter of the contact hole CH formed without providing the barrier metal BM1 and the contact material CM1 is the maximum.

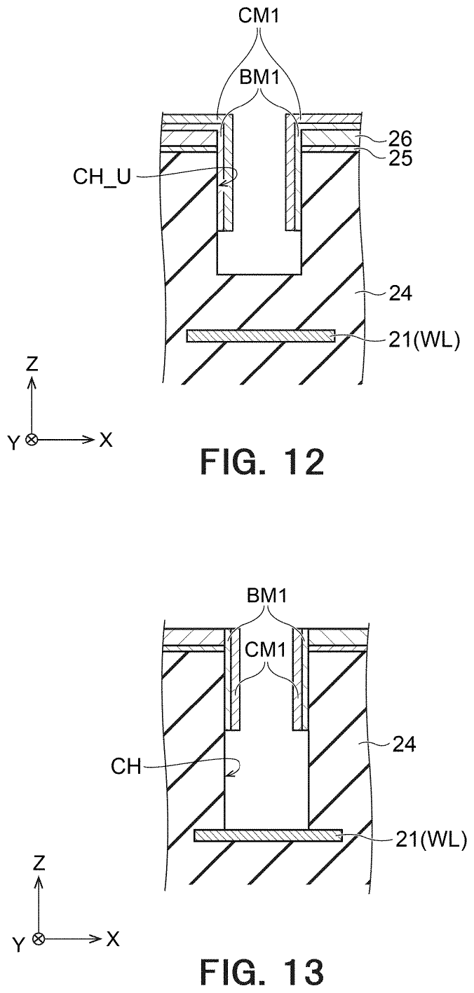

Next, as illustrated in FIG. 12, the contact material CM1 (for example, tungsten) is caused to selectively grow on the barrier metal BM1. Accordingly, the contact material CM1 is selectively formed on the barrier metal BM1, and is formed on the inner wall of the upper portion of the contact hole CH close to the opening end (the upper end), as with the barrier metal BM1. The contact material CM1 is hardly formed on the inner wall below that portion. The contact material CM1 also covers the inner wall of the upper portion CH_U of the contact hole CH over the entire length in the circumferential direction.

Next, as illustrated in FIG. 13, the lower portion of the interlayer dielectric film 24 is etched by RIE using the contact material CM1 and/or the barrier metal BM1 as mask, thereby making the contact hole CH penetrate to the electrode film 21. At this time, although the contact material CM1 and/or the barrier metal BM1 are/is also etched to some extent, the contact material CM1 and the barrier metal BM1 formed on the inner wall of the upper portion CH_U of the contact hole are left because of anisotropy of RIE. Accordingly, the inner wall of the upper portion CH_U of the contact hole is protected by the contact material CM1 and the barrier metal BM1, and therefore is not etched in directions within the X-Y plane and is not widened. Consequently, the inner diameter of the upper portion CH_U of the contact hole is substantially maintained to be the inner diameter in the formation process of the upper portion CH_U.

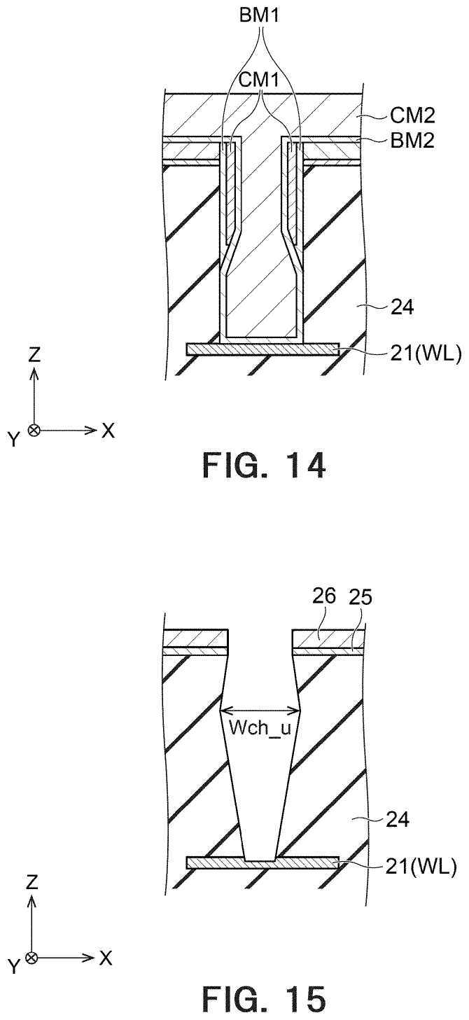

Next, as illustrated in FIG. 14, the barrier metal BM2 (for example, TiN) is deposited to cover the contact material CM1 in the upper portion CH_U of the contact hole CH and also cover the inner wall of the lower portion of the contact hole CH. That is, the barrier metal BM2 is formed to continue from the inner wall of the upper portion to the inner wall of the lower portion of the contact hole CH, and is connected to the electrode film 21. The barrier metal BM2 is deposited under a superior-coverage condition by high-temperature CVD with a process gas with a sufficient flow rate. By this deposition, the barrier metal BM2 is formed from the opening end (the upper end) to the lower end of the contact hole CH and covers the entire inner wall of the contact hole CH.

Next, the contact material CM2 (for example, tungsten) is caused to selectively grow on the barrier metal BM2 in the contact hole CH. Since the barrier metal BM2 is provided on the entire inner wall of the contact hole CH, the contact material CM2 is embedded inside the contact hole CH entirely.

Next, as illustrated in FIG. 7, the contact material CM2, the barrier metal BM2, the mask member 26, and the like on the interlayer dielectric film 24 are polished by CMP (Chemical Mechanical Polishing), or the like. At this time, the barrier metal BM1, the contact material CM1, the barrier metal BM2, and the contact material CM2 are stacked concentrically around the center of the contact hole CH in plan view as viewed from the Z-direction. Therefore, adhesion between the inner wall of the contact hole CH and its internal structure becomes high. Accordingly, in polishing by CMP, the barrier metal BM1, the contact material CM1, the barrier metal BM2, and the contact material CM2 are hardly separated from the inner wall of the contact hole CH even if they are exposed in a polished surface.

Thereafter, another interlayer dielectric film, a wiring layer (not illustrated), and the like are formed on the interlayer dielectric film 24 so that a semiconductor device according to the present embodiment is completed.

According to the present embodiment, in a process of forming the contact hole CH, it is possible to make the contact hole CH to penetrate through the interlayer dielectric film 24 to the electrode film 21, while the contact material CM1 and the barrier metal BM1 protect the inner wall of the upper portion CH_U, as illustrated in FIGS. 12 and 13. Accordingly, it is possible to form the contact hole CH with a high aspect ratio without excessively increasing the width in the X-Y plane (the inner diameter) of the upper portion CH_U of the contact hole CH.

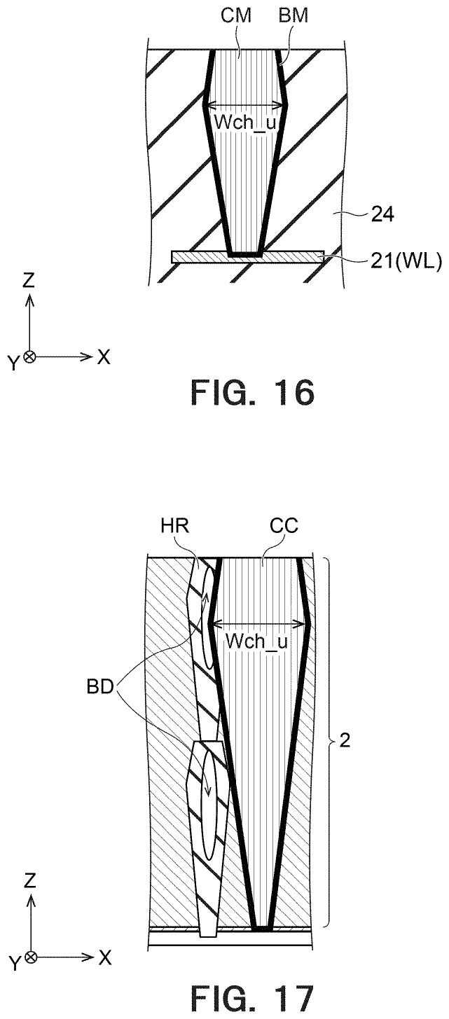

In a case where the contact material CM1 and the barrier metal BM1 are not provided and the contact hole CH is formed using the mask member 26 as mask, the inner wall of the upper portion of the contact hole CH is etched to some extent by an etching gas of RIE, as illustrated in FIGS. 15 and 16. FIG. 15 is a schematic cross-sectional view illustrating a configuration example of a contact hole CH according to a comparative example. FIG. 16 is a schematic cross-sectional view illustrating a configuration example of a contact plug CC according to the comparative example. As described above, the width in the X-Y plane (the inner diameter) Wch_u of the inner wall of the upper portion of the contact hole CH is increased. In a case where this contact hole CH is applied to the contact plug CC illustrated in FIG. 6, the contact plug CC may come into contact with the insulator column HR, as illustrated in FIG. 17. FIG. 17 is a schematic cross-sectional view illustrating a configuration example of the contact plug CC and its adjacent one of the insulator columns HR according to the comparative example. When the contact plug CC comes into contact with the insulator column HR, the contact material CM1 may enter into voids BD in the insulator column HR. When the contact material CM1 is connected to the electrode film 21 (the word line WL) of the stack 2 through the voids BD, it is likely that short circuit occurs between the contact plug CC and the word line WL and/or between the word lines WL.

Meanwhile, according to the present embodiment, the contact hole CH is formed while the contact material CM1 and the barrier metal BM1 protect the inner wall of the upper portion CH_U. It is thus possible to form a contact plug with a high aspect ratio while the width (the inner diameter) of the upper portion CH_U is maintained. In a case where this contact plug is applied to the contact plug CC, a distance can be ensured between the contact plug CC and the insulator column HR as illustrated in FIG. 6, whereby contact between the contact plug CC and the insulator column HR can be prevented. Accordingly, it is possible to prevent short circuit between the contact material CM1 and the word line WL or short circuit between the word lines WL.

In a case where the contact materials CM1 and CM2 are, for example, tungsten, it is likely that fluorine from the contact material CM1 or CM2 is diffused to a memory cell or a CMOS circuit because tungsten contains a lot of fluorine. However, in the present embodiment, fluorine is hardly diffused because the barrier metals BM1 and BM2 cover the outer circumferences of the contact materials CM1 and CM2 in the contact hole CH. In particular, the barrier metals BM1 and BM2 double cover the contact material CM2 in the upper portion CH_U of the contact hole CH. This configuration can more effectively prevent diffusion of fluorine from the contact material CM2 in the upper portion CH_U of the contact hole CH.

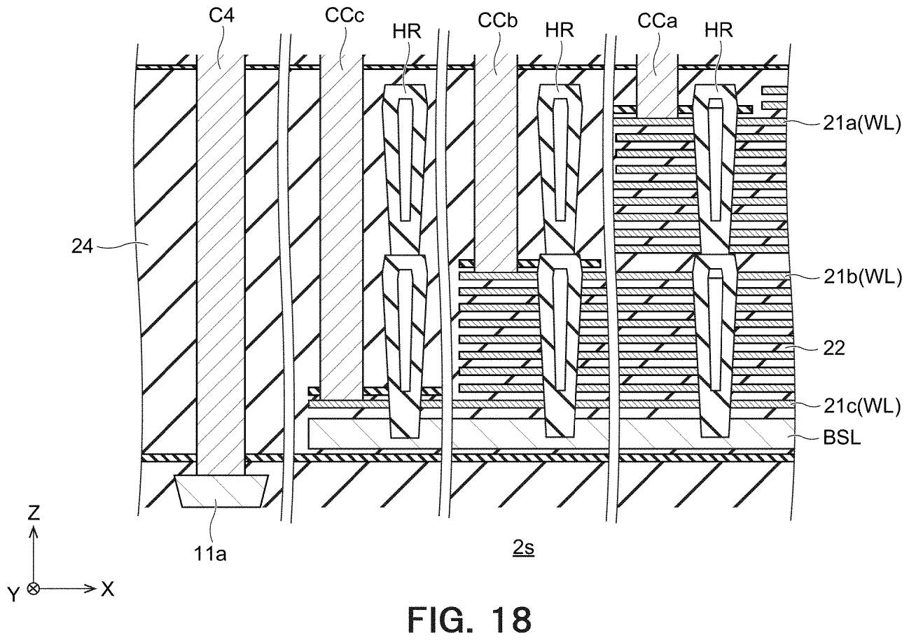

FIG. 18 is a schematic cross-sectional view illustrating an example in which a contact plug according to the present embodiment is applied to the contact plugs CC and C4 in the step portion 2s. The internal configurations of the contact plugs CC and C4 are identical to the configurations described referring to FIGS. 7 and 8, but illustrations thereof are omitted in FIG. 18. The electrode films 21 are provided in a stepped manner in the step portion 2s. The contact plugs CC penetrate through the interlayer dielectric film 24 in the Z-direction and are connected to terrace portions of the electrode films 21, respectively. The interlayer dielectric films 24 are provided not only above (in the Z-direction) the stack 2 of the electrode films 21, but also on a side (in the X or Y-direction) of the step portion 2s, as illustrated in FIG. 18.

For example, a contact plug CCa is connected to an electrode film 21a. A contact plug CCb is connected to an electrode film 21b. A contact plug CCc is connected to an electrode film 21c. The electrode films 21a, 21b, and 21c are provided at levels (positions in the Z-direction) different from one another and, in accordance with this arrangement, the depths of the contact plugs CCa, CCb, and CCc are different from one another. The contact plug CCc is formed to be the deepest among the contact plugs CC in order to be connected to the lowermost electrode film 21c. By applying the contact plug according to the present embodiment to such a contact plug CCc having a high aspect ratio, the contact plug CCc can be connected to the electrode film 21c without coming into contact with the insulator column HR. Naturally, identical effects can be obtained also in a case where the contact plug according to the present embodiment is applied to the contact plug CCa or CCb.

In FIG. 18, one of the insulator columns HR is illustrated for each of the contact plugs CCa, CCb, and CCc. However, the plural insulator columns HR are arranged around each of the contact plugs CCa, CCb, and CCc as described referring to FIGS. 5 and 6. Accordingly, the insulator columns HR serve as support members for the insulation layer 22 when a sacrifice film (for example, a silicon nitride film) is replaced with the electrode film 21 (for example, tungsten) in the above-described replacement process.

For example, the memory cell array 2m is formed in the following manner.

First, plural insulation layers 22 and plural sacrifice films are alternately stacked in the Z-direction to form the stack 2. Next, the memory hole MH is formed to extend in the stack 2 in the Z-direction, and the column portion CL is formed in the memory hole MH. Next, the sacrifice films are removed, thereby forming spaces between the insulation layers 22 adjacent to each other in the Z-direction. At this time, the insulator columns HR support the insulation layers 22 to prevent the insulation layers 22 from bending in the Z-direction and prevent the spaces from being crushed. Next, a material for the electrode film 21 is embedded in the spaces between the insulation layers 22 to form the electrode films 21 (the word lines WL) between the insulation layers 22. Accordingly, the memory cells MC are provided to correspond to respective intersections between the column portions CL and the stack 2. Next, the interlayer dielectric film 24 is formed above or on the side of the stack. After the step portion 2s is formed, the contact plugs CC are formed to extend in the interlayer dielectric film 24 in the Z-direction, and are connected to the respective electrode films 21. The memory cell array 2m is formed in this manner.

Further, the contact plug C4 connects a wiring layer (not illustrated) above the memory cell array 2m and the wire 11a of a CMOS circuit below the memory cell array 2m to each other. The contact plug according to the present embodiment may be applied to this contact plug C4. Accordingly, the contact plug C4 can be connected to the wire 11a without coming into contact with another structure adjacent thereto.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first electrode film;
an interlayer dielectric film provided on the first electrode film; and
a contact plug provided in a contact hole that penetrates through the interlayer dielectric film and reaches the first electrode film, wherein
the contact plug includes
a first metal film and a first conductive film configured to cover an inner wall of an upper portion of the contact hole,
a second metal film configured to cover the first conductive film on the inner wall of the upper portion of the contact hole and cover an inner wall of a lower portion of the contact hole, and
a second conductive film configured to be filled inside the second metal film in the contact hole.

2. The device of claim 1, further comprising:
a first stack of a plurality of first insulation films and a plurality of the first electrode films that are alternately stacked in a first direction; and
a first column body including a first insulator column extending in the first stack in the first direction, a first semiconductor portion provided on an outer circumferential surface of the first insulator column, and a charge trapping film provided on an outer circumferential surface of the first semiconductor portion, wherein
the interlayer dielectric film is provided above or on a side of the first stack, and
the contact plug is connected to one of the first electrode films.

3. The device of claim 2, wherein a plurality of the contact plugs are provided and connected to the first electrode films in one-to-one correspondence.

4. The device of claim 1, wherein
the first and second metal films are made of a same material as each other, and
the first and second conductive films are made of a same material as each other.

5. The device of claim 1, wherein
a metal material containing at least one of titanium nitride (TiN), tungsten nitride (WN), tantalum (Ta), tantalum nitride (TaN), and tungsten (W) is used for the first and second metal films, and
a metal material containing at least one of tungsten (W), cobalt (Co), nickel (Ni), molybdenum (Mo), and titanium (Ti) is used for the first and second conductive films.

6. The device of claim 1, wherein
the first metal film and the first conductive film end between the inner wall of the upper portion and the inner wall of the lower portion of the contact hole, and
the second metal film and the second conductive film continue from the inner wall of the upper portion to the inner wall of the lower portion of the contact hole.

7. The device of claim 1, wherein
the first conductive film is a film selectively formed on the first metal film, and
the second conductive film is a film selectively formed on the second metal film.

8. The device of claim 2, further comprising a plurality of insulator columns configured to extend in the first stack in the first direction and, as viewed from the first direction, arranged around the contact plug substantially evenly.

9. A manufacturing method of a semiconductor device comprising:
processing an upper portion of an interlayer dielectric film provided on a first electrode film to form an upper portion of a contact hole;
forming a first metal film on an inner wall of the upper portion of the contact hole;
forming a first conductive film to selectively cover the first metal film;
processing a lower portion of the interlayer dielectric film using the first conductive film or the first metal film as mask to make the contact hole penetrate to the first electrode film;
forming a second metal film to cover the first conductive film on the inner wall of the upper portion of the contact hole and cover an inner wall of a lower portion of the contact hole; and
embedding a second conductive film inside the second metal film in the contact hole.

10. The method of claim 9, further comprising:
alternately stacking a plurality of first insulation films and a plurality of sacrifice films in a first direction to form a first stack;
forming a first column body including a first insulator column extending in the first stack in the first direction, a first semiconductor portion provided on an outer circumferential surface of the first insulator column, and a charge trapping film provided on an outer circumferential surface of the first semiconductor portion; and
replacing the sacrifice films with the first electrode films, respectively, wherein
the interlayer dielectric film is formed above or on a side of the first stack, and
a contact plug provided in the contact hole is connected to one of the first electrode films.

11. The method of claim 9, wherein
the first metal film is formed on the inner wall of the upper portion,
the first conductive film is selectively formed on the first metal film,
the second metal film is formed to continue from the inner wall of the upper portion to the inner wall of the lower portion of the contact hole, and
the second conductive film is selectively formed on the second metal film.

12. The method of claim 10, wherein a plurality of the contact plugs are connected to the first electrode films, respectively.

13. The method of claim 9, wherein
the first and second metal films are made of a same material as each other, and
the first and second conductive films are made of a same material as each other.

14. The method of claim 9, wherein
a metal material containing at least one of titanium nitride (TiN), tungsten nitride (WN), tantalum (Ta), tantalum nitride (TaN), and tungsten (W) is used for the first and second metal films, and
a metal material containing at least one of tungsten (W), cobalt (Co), nickel (Ni), molybdenum (Mo), and titanium (Ti) is used for the first and second conductive films.
